(19) United States
(12) Patent Application Publication
(10) Pub. No.: US 2017/0179477 A1
(43) Pub. Date: Jun. 22, 2017

(54) A COMPOSITE MATERIAL

(71) Applicant: Perpetuus Research & Development Limited, London (GB)

(72) Inventors: Ian WALTERS, Ammanford (GB); Dylan WALTERS, Ammanford (GB)

(21) Appl. No.: 15/129,635

(22) PCT Filed: Mar. 27, 2015
(86) PCT No.: PCT/GB2015/050933

§ 371 Date: Sep. 27, 2016

(30) Foreign Application Priority Data
Mar. 28, 2014 (GB) 1405616.2

(51) Int. Cl. H01M 4/36; H01M 4/133; H01M 4/136; B82Y 30/00; H01M 4/38; H01M 4/58; H01M 4/62; H01M 10/0525; C23C 16/513; H01M 4/1393

(52) U.S. Cl. CPC H01M 4/366; C23C 16/513; C01B 31/02; C01B 31/04; H01M 4/133; H01M 4/136; H01M 4/1393; H01M 4/386; H01M 4/5815; H01M 4/621; H01M 4/625; H01M 10/0525; B82Y 30/00

(57) ABSTRACT

A composite material (1) is disclosed for use as an electrode (51) component comprising a first and second substantially separate and distinct graphitic material (2), (3). The first graphitic material (2) is spaced apart from the second graphitic material (3) and a decorate (6) is arranged within the space (4) between the first and second graphitic material (2), (3) by means of intercalation.

This invention relates to a composite material and in particular a nano-composite material for use in the electrodes of a rechargeable lithium ion battery.

Rechargeable lithium ion batteries are regarded as being the preferred energy source for many electrical applications including hybrid electric vehicles, mobile phones and lap-top computers. They comprise one or more electrochemical cells whereby each cell comprises an electrolyte, a positive electrode (anode) and a negative electrode (cathode). During discharge (or energy consumption) electrochemical reactions occur at the two electrodes, whereby lithium ions are sent from the anode to the cathode via the electrolyte, thereby generating a flow of electrons through an external circuit. The reactions are reversible, allowing the battery to be recharged by applying an external voltage across the electrodes, thereby storing electricity in the form of chemical energy. Traditional Lithium Ion batteries currently fail to meet expectations when considering energy density (which relates to how many lithium ions can be packed into the anode or cathode and life cycle). This failure is predominantly caused by the use of battery cathodes that fail to deliver the high energy densities that are usually required. Furthermore, the batteries charge rate is limited by the speed at which the lithium ions can travel through the electrolyte into the anode, and the morphology of the carbonacious material used for the electrodes. For example, if the material is graphite which is formed of layers of tightly packed sheets, during the charging process the lithium ions are required to travel to the outer edges of the graphene sheets prior to enabling transfer of the ions to the cathode. This results in the occurrence of an ionic log jam.

Traditional cathode materials include lithium iron phosphate, lithium cobalt oxide, lithium manganese oxide, lithium oxides with nickel and lithium vanadium oxide. However, because of its desirable high theoretical capacity of 1675 mAh/g sulfur has been considered as a component contender for lithium-ion batteries. Regrettably existing Li-sulfur arrangements have proven to be unsatisfactory for two reasons. Firstly, despite the high theoretical capacity, sulfur demonstrates very poor electrical conductivity. Secondly, the polysulfide shuttle phenomenon limits the effectiveness of sulfur cathodes. The polysulfide shuttle phenomenon is caused by the high solubility of the polysulfide anions during cycling of the battery. This leads to the speedy decay of the battery capacity and its life cycle.

Various solutions are known that attempt to improve the conductivity of sulfur cathodes. For example, incorporation of sulfur into cathodes in conjunction with carbon or a conducting polymer such as suffonated polystyrene, or other conducting channels has been demonstrated. However, none of the conducting media known have proven to improve the unfavourable effects caused by the polysulfide transfer. Other solutions explored have been predominantly based on improving the electrochemical performance of sulfur electrodes and consider immobilising the polysulfide's within the cathode by the inclusion of metal oxides. Electrolyte modification and the use of additives have also been applied, with varying success.

Optimisation of the anode is also an important consideration in order to optimise the characteristics of the Lithium ion battery. For example, an anode is produced using layers of carbon, the most popular material being graphite. Graphite accommodates one lithium atom for every 6 carbon atoms, however inclusion of silicon improves the energy density of the anode since silicon can accommodate more lithium ions (i.e. four Lithium atoms per silicon atom). However, when charging Lithium ion batteries which incorporate a silicon decorated anode, the silicon experiences a dramatic increase in its volume on insertion of the Lithium ions therein. On discharge the lithium is extracted from the silicon and the silicon returns to a smaller size. The silicon electrode when charged can expand to more than 3 times its dimension in the discharged state. The repeated expansion and contraction of the silicon within the electrode places a great strain on the silicon causing it to fracture or pulverise. This leads to electrical isolation of silicon fragments resulting in a loss of conductivity in the anode. The outcome is a short charge-discharge cycle of silicon based anodes. To overcome this problem, it is known for the silicon structure to be carefully designed so as to minimise the strain caused by the expansion and contraction of the silicon. For example it is known to use capsules to create a discontinuous layer allowing for the expansion and contraction of the silicon to be accommodated for. Also thin layers of silicon have also been found to be more effective than thicker layers, because they suffer less damage through cracking. However, in both cases the silicon layer is exposed to the electrolyte and a layer of lithiated compounds forms on the exposed Si surface. The charge and discharge cycling then causes small cracks to occur and for more of the silicon to be exposed. The lithiated compounds that form as a skin are insulating and as more of the silicon is exposed, the anodes capacity and cycling capability are degraded. To overcome this problem, protective layers have been implemented that permit the passage of the lithium, but prevent contact of the silicon with the electrolyte. However, this provides an extra protective layer of the anode that may have a detrimental effect to the charge characteristics of the anode. This includes a reduction in the specific surface area, whereby the specific surface area of a battery electrode is directly related to the specific capacity of the electrode. The binding layer also typically has an insulating characteristic that can lead to an increased internal resistance, resulting in a build-up of heat causing the power density associated with the electrode to be decreased, along with its output voltage.

A desirable application of Lithium Ion batteries is in off-grid energy storage, which is becoming more desirable to keep electricity grids reliable when utilised to exploit renewable energy generation, e.g. wind or solar energy. Large scale utility battery storage is needed which stores electricity in the form of chemical energy. Batteries are ideally suited for this application since they rapidly respond to load changes and accept co-generated and or third party power, thus offering a highly stable system. The low standby losses associated with batteries are also desirable. Unfortunately, traditional batteries are not deemed viable for large scale utility storage since they are hampered by low energy densities, small power capacity, high maintenance costs, short life cycle and a limited discharge capability.

A Stone Wales defect is a dipole of 5 to 7 ring pairs in a hexagonal network and is one of the most important defective structures for enabling the surface engineering of graphene or carbon Nano Tubes (CNTs). This defect can affect the mechanical, chemical and electronic properties of the graphene or CNTs. Single walled CNTs synthesised at 3000K via chemical vapour deposition are known to contain on average of one Stone-Wales defect per μm. These temperatures, however are extremely costly to provide over long periods of time.

Embodiments of the present invention are derived from the realisation that there exists the need to provide a composite material for use in electrodes for a Lithium ion battery which improves the characteristics associated with the Lithium ion battery enabling the Lithium Ion battery to be suitable for, in particular, large scale energy storage, for example for use in the national grid.

Therefore, the present invention and its embodiments are intended to address at least some of the above described problems and desires.

According to a first aspect of the invention there is provided a composite material for use as an electrode component comprising a first and second substantially separate and distinct graphitic material, the first graphitic material being spaced apart from the second graphitic material; and a decorate arranged within the space between the first and second graphitic material by means of intercalation.

The composite materials of the invention can demonstrate excellent friability. The ability to intercalate between the space or gap provided between the first and second graphitic material increases the surface area for receiving the decorate. This enables the graphitic material to be readily surface modified.

The composite material may have dimensions on the nano-scale so as to form a nano-composite material. Dimensions on the nano-scale may mean a characteristic dimension of less than 1000 nm. Particles of the invention may have a characteristic dimension of less than 1000 nm, but in some embodiments particles of the invention have characteristic dimensions (e.g., thickness and width) which are all 1000 nm or greater. The term “characteristic dimension”, as is generally understood and as is used herein, relates to an overall dimension of the particle considered as a whole entity. However, in general the separation between successive sub-structures and the stack thicknesses of the sub-structures are less than 1000 nm.

The first and second material may be the same material. Therefore, there is a major spacing arranged between respective surfaces of the first and second material of the same composition which forms the main body of the structure.

The first and second material may be platelet-like, rather than the external surfaces of, for example carbon nano tubes.

The first and/or second material have an undulating structure. This means that the spacing between the first and second material is variable, and in some regions respective surfaces may come into contact over a small contact area.

The first and second graphitic material are in a stacked arrangement so as to form a first and second layer of the stack and the decorate is positioned between the first and second layer of the stack. The first layer may be a first sub-structure and the second layer may be a second sub-structure, the first and second sub-structures including a stack of graphitic material layers, in which separation between successive stacked substructures is greater than the separation between successive graphitic material layers in each sub-structure. The separation between successive stacked substructures may be variable. The separation between successive stacked substructures increases the surface area of the graphitic material capable of receiving the decorate. The separation between stacked sub-structures may be at least 2 nm, preferably at least 5 nm, more preferably at least 10 nm. The separation between successive stacked substructures may be less than or equal to 100 nm, preferably less than or equal to 50 nm, more preferably less than or equal to 30 nm, most preferably less than or equal to 20 nm. The separation between successive stacked sub-structures may be in a range which extends from any of the lower bounds defined above to any of the upper bounds defined above. The separation between successive stacked sub-structures may be in a range 2 to 100 nm, preferably 5 to 50 nm, more preferably 10 to 30 nm, most preferably 10 to 20 nm.

The sub-structures may each have a stack thickness which is at least 0.7 nm, preferably at least 1 nm. The sub-structures may each have a stack thickness which is in the range 0.7 to 15 nm or less, preferably 0.7 to 4 nm or less. The sub-structures may each have a stack thickness which is in the range 1 to 15 nm or in the range 1 to 4 nm.

Each sub-structure may include a stack of between 2 and 12 graphitic material layers. It is possible for the particle to include single layers of graphene as well. Preferably the sub-structure may include a stack of 3 graphitic material layers.

Preferably, the graphitic material is graphene.

The sub-structures may be regarded as nanoplatelet-like sub-structures i.e. graphene nano-platelets GNPs which have a similarity since the basic sub-structure unit is a stacking of graphene layers. However the number of layers, their separation, the stack height and the width of the substructures may be similar or dissimilar to GNPs. In a number of embodiments, the sub-structures and the nanoparticles themselves exhibit a wavy or undulating topography.

The substructures each have a stack thickness. The stack thickness may be less than the separation between successive stacked sub-structures. The composite material may have a thickness in the range 0.7 to 5 microns, preferably 1 to 5 microns, more preferably 1.5 to 3 microns. For the avoidance of doubt, the term “thickness” relates to a dimension along which the sub-structures are stacked.

The composite material may have a width in a range of 1 to 15 microns, preferably 1 to 5 microns, more preferably 2 to 5 microns. For the avoidance of doubt, the term “width” relates to a dimension which is perpendicular or significantly perpendicular to the dimension corresponding to the thickness of the nanoparticle. The first and second material (or sub-structures) may have a nett negative charge. Without wishing to be bound by any particular theory or conjecture, it is believed that the presence of the net negative charge may at least assist in producing and retaining the relatively large separations between the first and second layer (i.e. the sub-structures) in relation to the separation between successive graphene layers in each sub-structure. Again, without wishing to be bound by any particular theory or conjecture, it is believed that the presence of the net negative charges may at least assist in enhancing friability.

The decorate may be an electro-active material. The electro-active material may enhance the electrical conductivity of the material and/or the electrical capacity.

The first and/or second layer may contain defects or holes arranged therein for permitting the transfer of ions there-through.

The composite material takes the form of a powder particle.

The external surface of the composite material may be substantially devoid of any decorate.

In a second aspect of the invention there is provided a surface transferable material including at least one above-mentioned composite material combined with a host rheological material. Therefore, a composite material dispersion is provided whereby the composite material is dispersed in a liquid medium.

The rheological material or liquid medium is a solvent. The composite material and the rheological material or liquid medium may form a slurry, or alternatively, they may form an ink which is printable using standard printing techniques. The surface transferable material includes a plurality of composite particles of the first aspect of the invention. The nano-particulate material may have a typical surface area in the range of 15 to 70 m² g⁻¹, preferably about 25 m² g⁻¹, which is the surface area of the stacks presented for mixing. The mixing shearing process liberates the graphene by shear forces and the surface area is then elevated to about 700 m² g⁻¹.

In a third embodiment of the invention there is provided an electrode, for use in an energy storage device, for example a battery, a rechargeable battery or a lithium ion battery comprising the above-mentioned composite material. The electrode has the above-mentioned surface transferable material applied thereto. The surface transferable material is applied to the surface of a conductive membrane.

The decorate material may be an active cathode component selected from the group comprising Cobalt-based lithium-ion, Nickel Cobalt Aluminium, Spinel-based lithium-ion, Nickel Cobalt Manganese, Lithium Iron Phosphate and sulfur, thereby forming a negative electrode.

The active cathode component is covalently bonded to a surface of the first and second material.

The electrode may also include nitrogen. At least some of the graphitic material layers. E.g. graphene layers, may be doped with Nitrogen. N doping provides N-type (negative) graphitic material structures which can improve the electrical conductivity. Nitrogen doping has proved to be an effective method to improve both microstructure and electrochemical properties.

The decorate applied to the graphitic material may be silicon. The silicon decoration is applied in the form of a plurality of discrete deposits of the material at a number of different sites on the graphitic material. This provides a plurality of discrete structures or ‘islands’ of silicon. The silicon applied may be a substantially spherical structure. Preferably, wherein the silicon has a nano-pod structure. This gives rise to useful properties, such as an ability for the silicon structures to expand and contract independently of each other. This provides the potential for the material to cope with multiple electrical charge-discharge cycles. Therefore, the spacing between the first and second material permits expansion and contraction of the silicon when a charging cycle is applied.

In a fourth aspect of the invention there is provided a method of making a composite material of the first aspect of the invention including subjecting the starting material to a plasma treatment. In the method at least one space is created between a first and second graphitic material and subsequently the electroactive material is inserted within the at least one space by means of intercalation. Alternatively the creation of the space between the first and second graphitic material and the insertion of the electroactive material by means of intercalation are performed contemporaneously. For example, the graphite starter material may be opened up into graphene stacks and the intercalate may be inserted between the graphene stacks contemporaneously.

The plasma treatment may include generating plasma using a plurality of electrodes which are moved through the target material during the plasma treatment to agitate and provide intimate contact with a high density of sub-atomic particle bombardments (that reside close to the electrodes) displace atoms and provide particle defects, primarily Stone Wales defects that provide the anchor point to host decorations and cause sheets to bend and form waves and spaces necessary for intercalating the starting material and/or the composite material. Apparatus suitable for making the composite material of the invention are described in the Applicant's co-pending International application PCT/GB2014/053352 filed on 12 Nov. 2014 and co-pending UK patent applications 1322764.0, filed on 22 Dec. 2013, and 1319951.8, filed on 12 Nov. 2013, the entire contents of each of which are incorporated by reference. These documents also disclose methodologies which may be adapted to produce the composite material of the invention.

Without wishing to be bound by any particular theory or conjecture, it is believed that the electrodes provide intimate contact between the starting material and/or the composite material and a high density of one or more of molecules, atoms, sub-atomic particles and photons at positions close to the electrodes.

This displaces atoms in the starting material and/or the composite material and provides defects such as Stone Wales defects that provide anchor points e.g., to host functionalities and/or decorations and/or cause graphene sheets to bend, assume a wavy topography and/or provide the gaps between sub-structures.

For example, intimate contact is provided at high impact velocities between localised ion beam or electron radiation at a region close to the cathode and in the presence of graphitic material e.g. graphenes. This intimate contact provides temperatures of up to 3000K for a time period of nano second. As such, the conditions necessary for the creation of Stone Wales defects are established, albeit momentarily. This localised temperature provided as a result of the ‘intimate contact process’ is significantly higher than the ambient temperature of the plasma chamber, which is typically in the region of 340K. The Stone Wales defects are long lived after the initial synthesis, and are trapped in the lattice of the graphitic material by the high dissolution barrier.

The invention provides numerous ways in which the starting material and/or the nanoparticles can be treated. The relevant treatments that apply to the fabrication of the composite material of the invention are discussed below.

i) Exfoliation

The plasma treatment may include an exfoliating plasma step for exfoliating the starting material. The exfoliating plasma step may use a noble gas plasma. A noble gas is understood to be a gas of Group 18 of the periodic table. The exfoliating plasma step may use an argon plasma.

ii) Cleaning

The plasma treatment may include a cleaning plasma step. The cleaning plasma step may use a plasma in an oxygen containing gas, such as an oxygen plasma. Mixtures with inert gases may be used.

The order of the cleaning and exfoliating steps is interchangeable. However, good results have been obtained performing a cleaning step before an exfoliation step.

iii) Generating Defects

Stone Wales defects further pushes the layers or sub-structures of the graphitic material apart enhancing friability. Stone Wales defects may act as anchor points for functionalisation, decoration and doping.

iv) Intercalation and Doping

Intercalation between the first and second material is possible, whereby the first and second material includes a first and second sub-structure respectively. Doping can also be performed to introduce dopants into the bulk structure of the graphitic material. The graphitic structure mat be doped with Nitrogen. The use of doping procedures which does not use a plasma is also within the scope of the invention.

v) Decoration

The treatment may be performed to decorate the surface of the particles with a decoration material. Silicon decoration may be performed using a plasma treatment with a suitable silicon containing precursor gas vapour such as siloxane. An example of a precursor is hexamethyldisiloxane. Alternatively, the surface of the particles may be decorated with a binding material typically Polyethylene Polypropylene or a rubber (such as Nitrile Butadiene or Styrene Butadiene rubber).

For the avoidance of doubt, the term ‘gas’ as used herein includes any substance introduced to the plasma in gaseous form, including the gaseous component of a volatile liquid such as siloxane.

The method may include a finishing treatment. The finishing treatment may be performed to produce a desired effect or property. The finishing treatment may include a high temperature treatment and/or a plasma treatment.

The finishing treatment may include a microwave induced finishing treatment. Preferably, the microwave induced finishing treatment is a microwave induced plasma treatment. The composite material may be directly exposed to microwave radiation. A microwave oven may be used to directly expose the composite material to radiation. A microwave induced finishing treatment may be used to convert the composite material, which are coated with silicon to provide a composite material having a plurality of discrete structures or ‘island’ of silicon.

The plasma treatment may utilise a glow discharge plasma. Plasmas of this type are convenient to implement and have been found to produce good results.

Generally speaking, glow discharge plasma is a low pressure plasma. The pressure used to generate the glow discharge plasma is typically 10 Torr or less. Preferably the pressure used is 5 Torr or less, more preferably 1 Torr or less, more preferably still, 0.5 Torr or less and most preferably 0.1 Torr or less. The pressure used is typically 0.001 Torr or greater, and often 0.01 Torr or greater. For the avoidance of doubt, ranges of pressures corresponding to all possible combinations of these upper and lower pressure limits are within the scope of the invention.

In general the glow discharge plasma is formed by the passage of electric current through a low pressure gas. The glow discharge plasma may be formed using DC, AC or RF voltages.

Although, it is preferred to use glow discharge plasma, it is possible to generate other types of plasma. For example, atmospheric plasmas, near atmospheric plasmas, or plasmas utilising pressures up to several atmospheres might be utilised. Alternatively, other forms of low pressure plasma might be used.

Plasma is formed in a localised region around a working electrode of the treatment chamber. In combination with the use of a plurality of electrodes to agitate the particles during the plasma treatment, this feature enables the interaction between the plasma and the particles to be well controlled. It can also enable advantageous processing conditions to be created and controlled.

The starting material may contain a graphitic material. The graphitic material may be a material containing graphene stacks such as GNPs, fullerenes such as bucky balls and CNTs, or a mixture thereof.

Alternatively the starting material may include a clay or another carbon containing material.

In a sixth aspect of the invention there is provided a method of fabricating a composite material including creating at least one space between a first and second graphitic material and subsequently inserting electro-active material within the at least one space by means of intercalation. This differs to known techniques which creates the space subsequent to wrapping the graphene around the electro-active material.

In a seventh aspect of the invention, there is provided a method of fabricating a composite material in a plasma chamber including: inserting a raw carbonacious material into the chamber; twisting and buckling the raw carbonacious material by the application of a plasma to form a host region, and inserting an electro-active material within the host region so as to form a composite material. The method may use an exfoliation process for causing the twisting and buckling of the stacks of raw carbonacious material. The method may further comprise the step of applying a cleaning process on the raw carbonacious material prior to the twisting and buckling of the raw carbonacious material.

The method may use a second cleaning process for substantially removing any electro-active material located on the external surface of the composite material. The electroactive material may be inserted by sulfur sublimation.

In an eighth embodiment of the invention, there is provided a method of forming an anode comprising placing a graphitic material within a plasma chamber; cleaning the graphitic material within a plasma chamber; cleaning the graphitic material with a plasma formed in the presence of argon gas; functionalising the graphitic material with a plasma formed in the presence of oxygen gas; and introducing polydimethylsiloxane hexamethyldisiloxane vapour into the plasma chamber so as to insert silicon within the graphitic material.

In a ninth embodiment of the invention, there is provided an energy storage device, for example a battery or a rechargeable battery incorporating the material of the first aspect of the invention. The rechargeable battery may be a Lithium Ion battery.

In a tenth aspect of the invention the energy storage device comprises a rechargeable battery which incorporates the electrode of the third aspect of the invention, whereby the decorate is sulfur.

In a eleventh aspect of the invention the energy storage device comprises a rechargeable battery which incorporates the electrode of the third aspect of the invention, whereby the decorate is silicon.

In a twelfth aspect of the invention, the energy storage device comprises a rechargeable battery which incorporates a first electrode comprising the third aspect of the invention, whereby the decorate is sulfur and a second electrode comprising the third aspect of the invention, whereby the decorate is silicon. Therefore, the cathode and anode are provided respectively.

In a thirteenth aspect of the invention, there is provided a method of producing a defect in a graphitic material in a plasma chamber comprising: providing an impact between the graphitic material and a localised ion bean, electrons or radiation at a region proximate to an electrode so as to produce a localised temperature at that region which is greater than the ambient temperature within the plasma chamber so as to produce a defect in the graphitic material. The radiation may, for example, be electron radiation.

The ambient temperature within the reactor may be less than 400K and the localised temperature at the electrode is more than 550K. The localised temperature may be less than 3000K.

The localised temperature may occur for a time period of less than 10 nano seconds.

Whilst the invention has been described above it extends to any inventive combination of the features set out above, or in the following description, drawings or claims. For example, any features described in relation to any one aspect of the invention is understood to be disclosed also in relation to any other aspect of the invention.

The invention will now be described, by way of example only, with reference to the accompanying drawings, in which:—

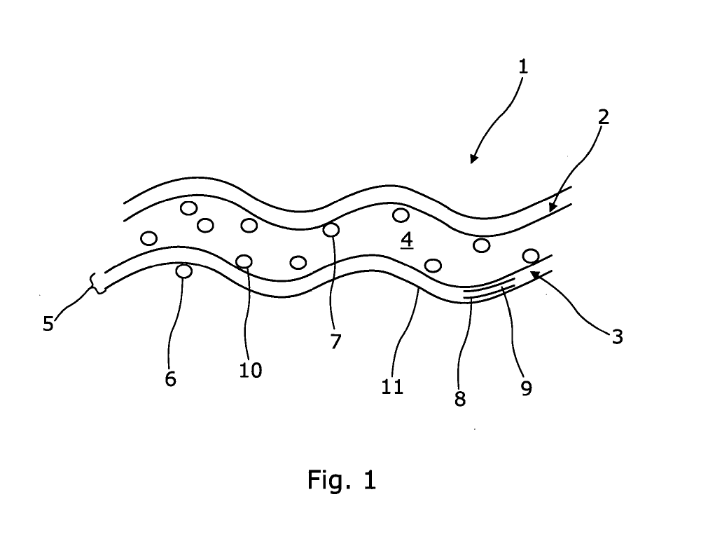

FIG. 1 is a schematic representation of a composite material;

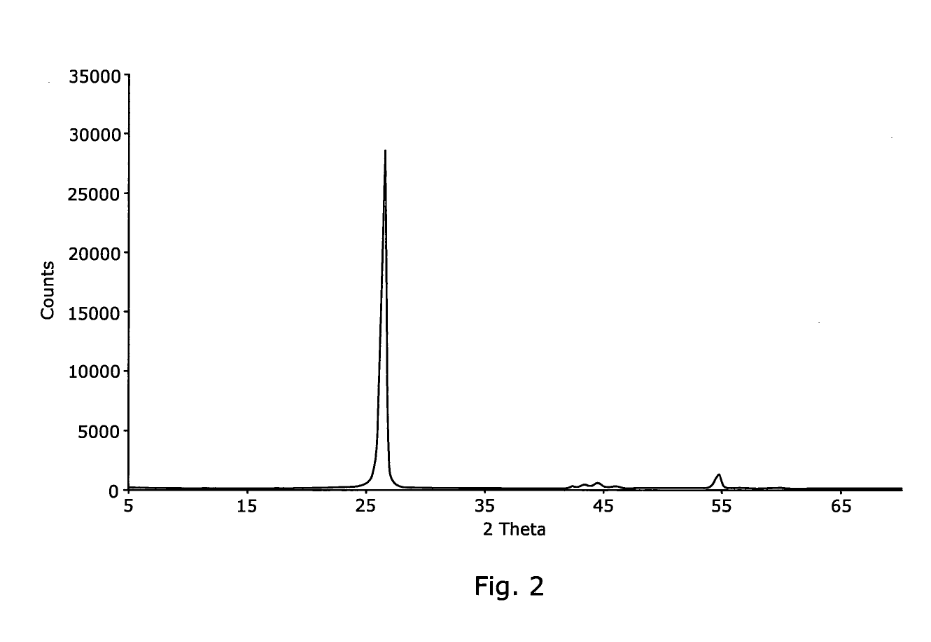

FIG. 2 is a plot to show the crystallinity of the material;

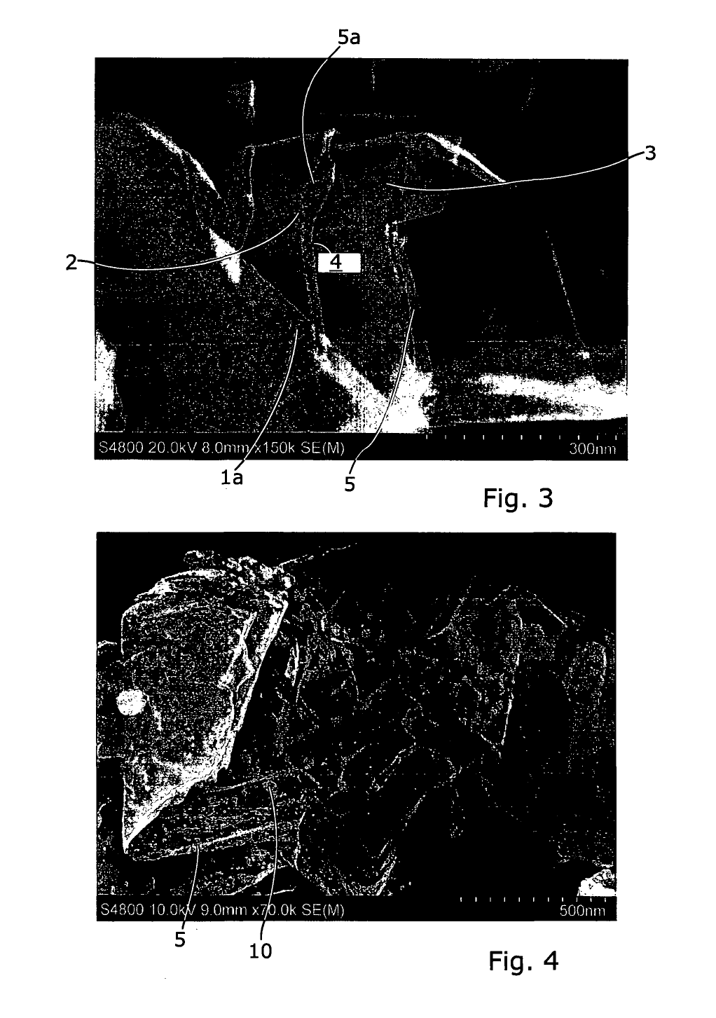

FIG. 3 is a Scanning Electron microscope (SEM) image of the graphitic material;

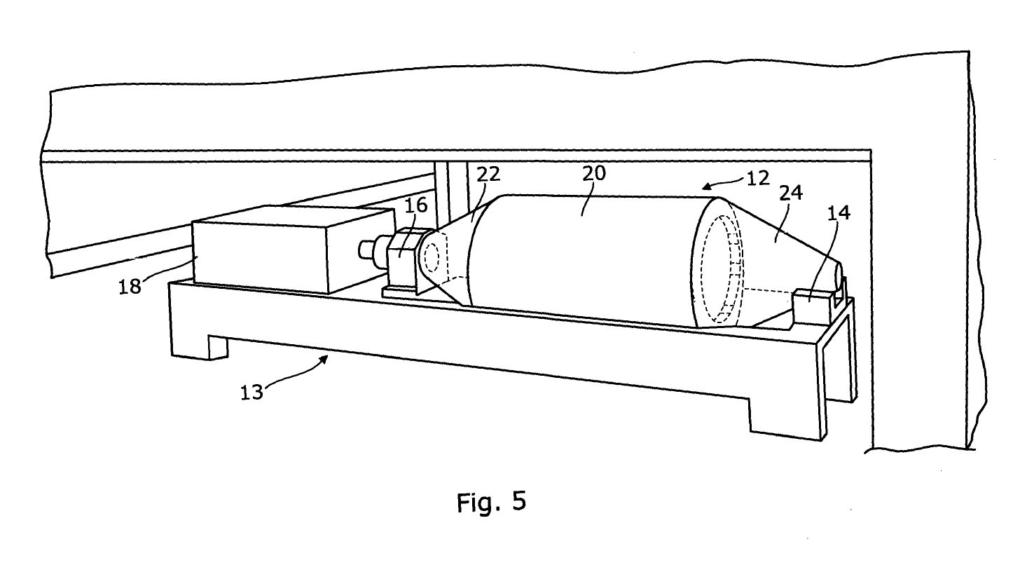

FIG. 4 is a Scanning Electron microscope (SEM) image of a composite material including Silicon nano-pods;

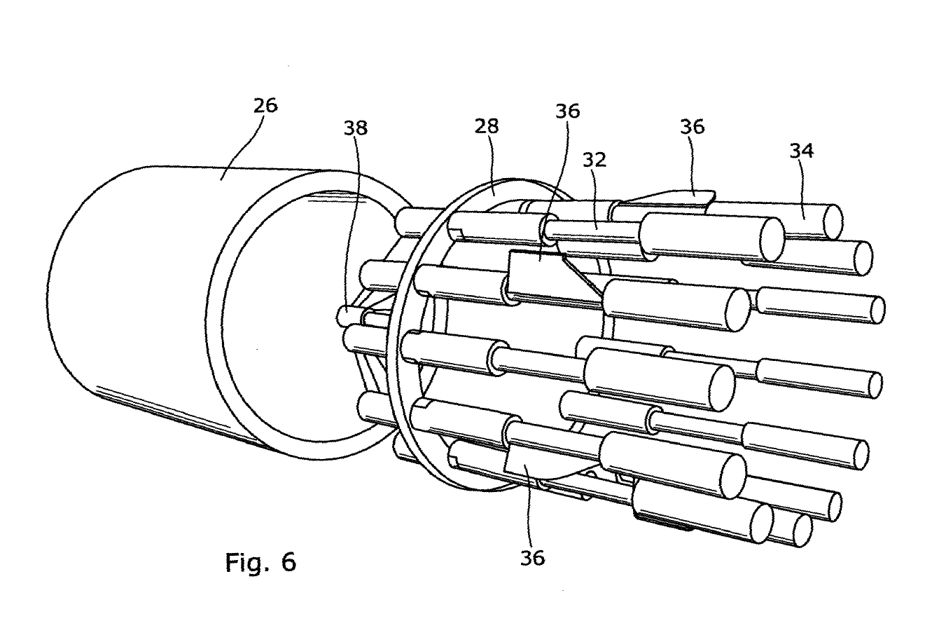

FIG. 5 is a perspective view of apparatus of the invention

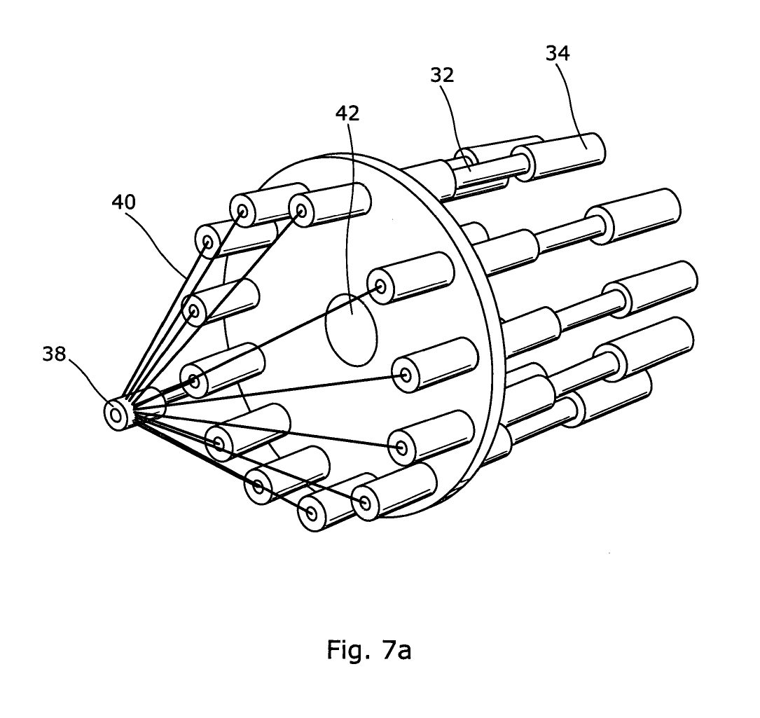

FIG. 6 is an exploded view of the interior of the rotating drum;

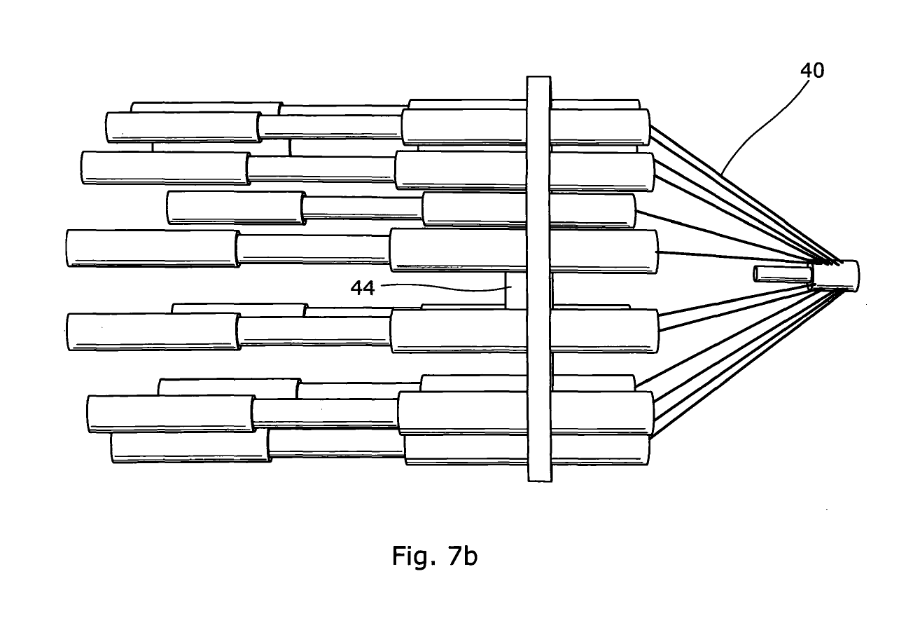

FIG. 7 shows (a) an exploded perspective view and (b) a side view of an end plate having a plurality of electrodes disposed therein.

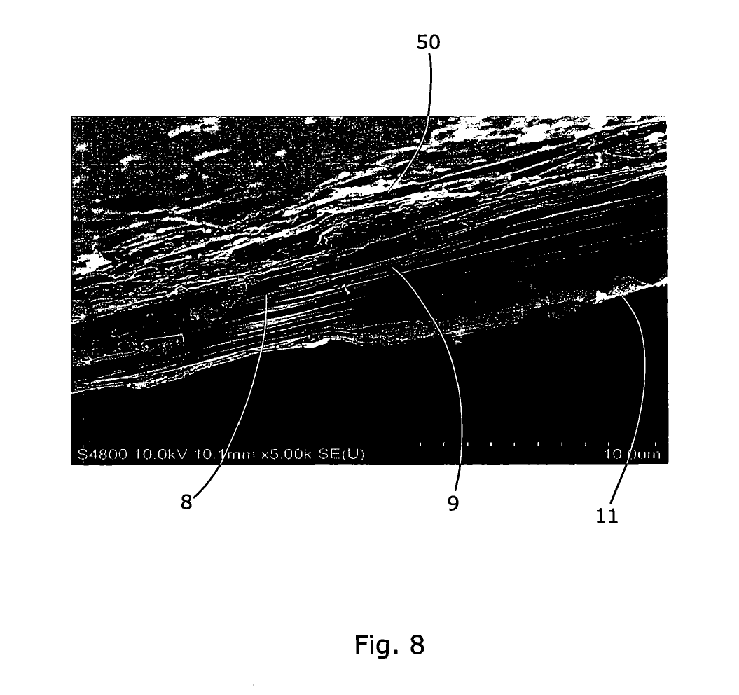

FIG. 8 shows an SEM image of a graphitic starting material;

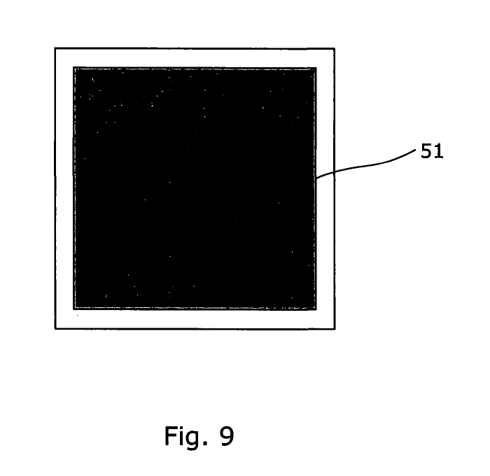

FIG. 9 is an image of an electrode;

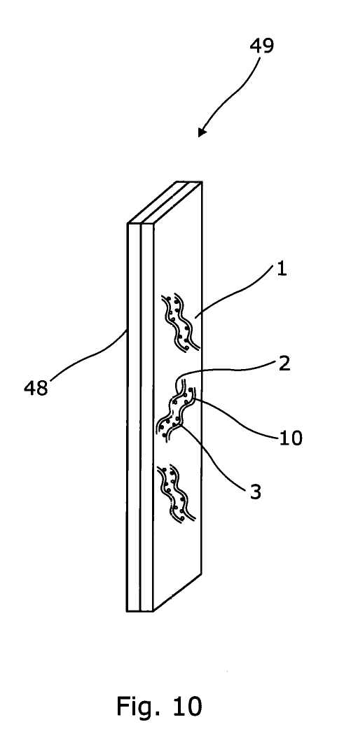

FIG. 10 is a schematic of an anode;

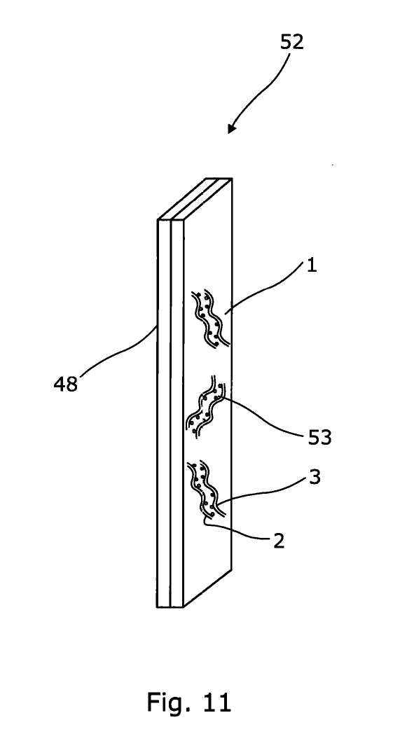

FIG. 11 is a schematic of a cathode; and

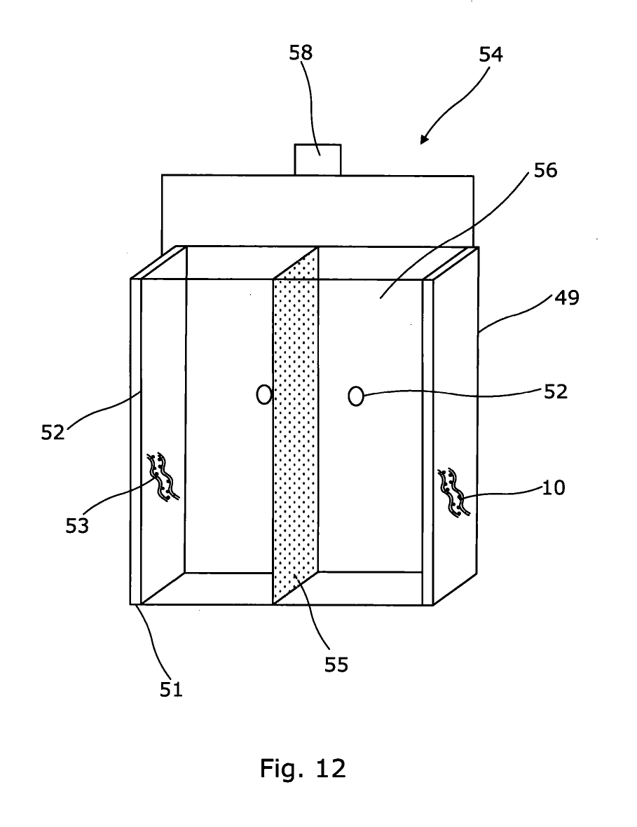

FIG. 12 is a schematic of a rechargeable Lithium Ion battery.

Referring firstly to FIG. 1, there is shown a schematic representation of a composite material 1 comprising a first and second graphitic material 2, 3, the first material 1 being spaced apart from the second material 2.

Without wishing to be bound by any particular theory or conjecture, it is believed that the first and second material (or sub-structures) have a net negative charge which acts to keep the first and second material (or sub-structures) apart. Defects are provided, e.g. Stone Wales defects that gives rise to the relatively large separations between sub-structures. It is believed that the relatively large major gaps (or spaces) 4 between sub-structures or layers improve friability of the material 1, whereby application of a small force will overcome the force that holds the first and second material 2, 3 in a predetermined spaced arrangement. This gives rise to improved packaging, handling and incorporation of the material into a liquid media. In contrast, prior art nanoparticles such as CNTs, GNPs and single flakes of graphene are notoriously difficult to handle, and commonly exhibit a high degree of entanglement and poor friability. This is ultimately because the prior art exhibits relatively flat stacked structures that have sized gaps between the layers that are unable to host intercalate, since the spacing is too small.

A further advantage associated with the relatively large gaps 4 is that a decorate material 6 can be intercalated into the gap or space 4 between the first and second material 2, 3. To enable this, the space 4 between the first and second material 2, 3 is a minimum of 2 nm. The graphitic material 1 as shown in FIG. 1 has an undulating morphology, whereby the layers of a starting material, for example a graphite, have been twisted and buckled so as to provide graphene flakes that have a random waved morphology with the gaps or spaces 4 being provided between the undulating graphene layers 5. Electro-active materials are used as the intercalate 7 which are inserted into the gaps 4 subsequent to the gaps being formed. This differs to known techniques in the prior art whereby the graphitic material is wrapped around electro-active material of interest. Therefore, in the prior art the space is created only after the electro-active material has been provided. The wrapping process is cumbersome and the resulting capsule has many overlap regions that has a low degree of crystallinity.

The provision of the gaps 4 prior to introducing the electro-active material 7 therefore increases the surface area of the graphitic material 2, 3 enabling more electro-active material 4 to be accommodated in the composite material 1 compared to other known structures. Further, the composite material 1 of the invention is a flexible yet highly crystalline structure which has been revealed by XRD analysis whereby both the alpha graphitic form (hexagonal) and beta graphitic form (rhombohedral) have been observed. This high level crystallinity facilitates conductivity through the material. This therefore provides a conductive framework for electrode transport making it suitable for use in, for example, an electrode. A comparison between the crystallinity of the stacked arrangement of the invention compared to a known material is shown in FIG. 2. It is clear that the graph of the stacked material is highly crystalline and this is significantly sharper than that of the known stacked or wrapped arrangements.

In plane defects or vacancies (not shown) are also included in the morphology of the graphene layers 2, 3 providing a shortcut for free ion travel, which, for example, is applicable for Lithium ions.

FIG. 3 shows the graphitic material comprising several layers 5. Commonly, there are observed a first plurality of successive sub-structures 5 having edges that are substantially in alignment, followed by a second group of successive substructures 5a having edges which are substantially in alignment, but which are not necessarily aligned with the first plurality of sub-structures 5, and so on. It has been shown that each sub-structure 5 comprises a number of layers of graphene 8. Typically there are about ten layers of graphene 8 in each sub-structure 5. Often, sub-structures 5 are observed to have about three graphene layers 8 with a substructure thickness of about 2.1 nm. The minor gaps 9 between successive layers 8 in the sub-structures 5 are about 0.5-0.8 nm. It will be appreciated that individual graphene layers 8 are not resolved in FIG. 3 and instead the sub-structures 5 appear as apparently discrete features.

FIG. 4 shows a composite material 1 with silicon 10 as the intercalate 7. It is shown that the composite material 1 is relatively clean of electro-active decorates 6 on the external surface 11 whilst retaining the inner decorates 7 within the gap 4 between the first and second graphitic material 2, 3. This arrangement minimises interaction of decorates 6 with external substances, for example electrolyte.

The composite material 1 is processed in a plasma chamber which sustains the plasma by introducing a gas or gaseous mixture therein. The apparatus as shown in FIGS. 5 to 7b was used and will now be described.

Apparatus suitable for producing nanoparticles of the invention will now be described. FIG. 5 shows a suitable treatment chamber 12 positioned on a bed 13 through coupling portions 14, 16. The coupling portion 16 is in operative connection with a suitable motor or actuator disposed in a housing 18. The motor or actuator is coupled to the treatment chamber 10 so that, in operation, the treatment chamber 12 may be rotated at a desired rotational speed.

The treatment chamber 12 is a three-part modular arrangement comprising a central drum 20 and first and second frusto-conical sections 22, 24. The first frusto-conical section 22 is in contact with the receiving portion 16, and second frusto-conical section 24 is in contact with the receiving portion 14 so as to allow the treatment chamber 12 to be rotated. The drum 20 and first and second frusto-conical sections 22, 24 can be formed from any suitable material, such as stainless steel.

FIG. 6 shows the internal arrangement of the drum 20 in more detail. In particular, the drum 20 comprises a cylindrical portion 26 and a first circular end plate 28. The first end plate 28 is in communication with the first frusto-conical section 22. A second circular end plate (not shown) is positioned at the end of the cylindrical portion 26 opposite the first end plate 28 and is in communication with the second frusto-conical section 24. A plurality of electrodes 32 project out of the first end plate 28 into the interior of the drum 20. The electrodes 28 are radially disposed around the longitudinal axis of the drum 20 in a circular pattern. As shown in FIG. 6, the electrodes are equally spaced, although it is not critical that this is so. The electrodes 28 are arranged towards the circumferential edge of the first end plate 28. As explained in more detail below, this arrangement is preferred in order to provide agitation of particles which are disposed in the treatment chamber in order to undergo plasma treatment. In the embodiment shown in the figures, an arrangement of twelve electrodes project into the treatment chamber. However, a greater or a lesser number of electrodes might be used. In the embodiment shown in the figures, the electrodes 32 are formed from an electrically conductive material such as stainless steel. Isolator sleeves 34 formed from an electrically insulating material such as ceramic are disposed at both ends of each electrode 32. The sleeves may be coatings on the electrodes. The electrodes should generally be arranged to project a significant way into the chamber. The active plasma producing areas of the electrodes may be coated with a conductive ceramic coating such as boron silicate glass. This can act to reduce unwanted sputtering.

The supply and removal of gases to and from the treatment chamber 12 will now be described with particular reference to FIG. 7 which shows a gas inlet module 38 (also shown in FIG. 6) which is in gas conducting connection with a plurality of gas inlet lines 40. Each gas inlet line 40 is connected to an electrode 32. Each electrode 32 is hollow, having an internal gas conducting conduit (not shown) leading to a gas outlet aperture at the distal end of each electrode 32 (not shown). The gas inlet module 38 is housed in the first frusto-conical section 22, and is supplied with the gases to be used during plasma processing from one or more external gas supply sources (not shown). The supply of gas can be controlled using known means such as mass flow controllers.

The first end plate 28 has an exhaust port 42 formed therein. As shown in FIG. 8(b), a filter 44 is disposed in the exhaust port 42. The exhaust port 42 is in connection with a pumping arrangement (not shown) which is used to create a vacuum in the treatment chamber and to pump away process gases in a manner which is well-known to the skilled reader.

Rotatable drum chambers are available commercially and may be adapted in order to produce apparatus of the invention. For example, a rotating drum plasma reactor is produced commercially by Diener Electronic GmbH & Co. KG, D-72224 Ebhausen, Germany having the product name “Tetra 150”®. This apparatus may be adapted in accordance with the invention, for example by providing the plurality of electrodes described above.

In use, a charge of the starting material is disposed on the floor of the drum 20. The chamber is evacuated to a desired baseline pressure, and the process gas or gases are introduced into the treatment chamber 20 through the electrodes 32. The treatment chamber 12 is rotated at a desired rotational speed. A plasma is generated at each electrode 32 in order to initiate processing of the particles. During the processing of the particles, the electrodes 32 are rotating, and this acts to continuously agitate the charge of particles in the treatment chamber. The particles may be physically transported through this agitation, for example through sideways displacement of the particles, or by way of the particles being thrown upwards the interior of the chamber. Scoops 36 can significantly assist in the process.

In the embodiment shown in FIGS. 5 to 7, glow discharge plasmas are formed at each electrode 32. RF power is applied to electrode 32. A convenient RF frequency such as 13.56 MHz may be used. The electrodes 32 thereby act as working electrodes in a glow discharge system. A counter-electrode is provided, and conveniently this can be the inner surface of the drum 20 which might be coated with a conductive ceramic such as boron silicate glass. The RF power establishes a negative DC bias voltage on the electrodes 32 which thereby act as cathodes in the flow discharge system. It is also possible to use other methods to obtain glow discharge plasmas, such as through the application of a DC voltage through electrodes 32. Other forms of plasma might be utilised instead.

Localised plasmas are generated around each electrode 32, but the process conditions are selected so that these plasmas are discrete and separated from one another. In this way, each electrode is surrounded with a plasma halo which contains clouds of energetic electrons, UV photons, ions and, typically, reactive neutral species. This rich plasma is used to produce the composite material. The use of multiple electrodes increases the number of electron clouds and other useful species associated with the plasmas, and this has beneficial effect on processing efficiency. Additionally, the use of the electrodes to agitate the particles to be treated can also have a beneficial effect on processing efficiency as well as improving the results achieved.

The apparatus may be used to exfoliate a graphitic starting material. Typically a high plasma power is utilised, at least in the initial stages of the process, to facilitate ion bombardment and ion intercalation of the target material. For example, powers of up to 2000 W can be used. Effective bombardment and intercalation causes layers of the starting material such as graphite to exfoliate. Without wishing to be limited by a particular theory or conjecture, it is believed that a result of this is that a nett negative charge is imparted onto the exfoliated layers so that they can push off from each other. Stone Wales forces are also used to push the adjacent layers further apart. This charge overcomes attractive van der Waals' forces, thereby retarding the usual inclination of the particles produced by the exfoliation to re-agglomerate. A plasma formed in argon or oxygen is effective in producing exfoliation.

A cleaning step may be provided before, during or after the exfoliation step. An oxygen plasma is an advantageous means of cleaning. Representative but non-limiting process conditions are a temperature of less than 100° C. with a plasma power of 120 W for around thirty minutes at a pressure of 1.5 Torr. Higher powers can be used.

A further possibility is to remove nanoparticles from the multi-electrode treatment chamber to a final stage treatment chamber using vacuum transfer or other appropriate means. The final treatment chamber may be used to facilitate high temperature processing which will provide additional treatment options, for example for decorating the nanoparticles with a desired material. The final stage treatment may be a microwave induced plasma treatment. In these embodiments, the final treatment chamber may have glass windows and an inner surface coated with a ceramic or glass. Appropriate wave guides are used to couple microwave energy into the chamber through the windows. The final treatment chamber can be configured to rotate in order to agitate the nanoparticles. A modified version of the FER 500 product described above can be used for this purpose. In another alternative, a final treatment step such as this can be performed in the original treatment chamber. In these embodiments, the original treatment chamber is provided with microwave means to generate the microwave induced plasma. The multi-electrode array can be used for this purpose if the electrodes are made from suitable materials such as a conductive glass, for example boron silicates.

A potential problem during processing is electrical shorting of the electrodes. This can be at least ameliorated by reducing the plasma power as the processing continues. The likelihood of shorting occurring increases if the material volume increases during processing which is likely to occur if deagglomeration and/or disaggregation occurs. One approach which may be adopted is to reduce the plasma power as the volume of the nanoparticles increases. For example, an inverse relationship between the volume of the nanoparticles and the applied plasma power, or another relationship determined by routine investigation may be followed.

### Production of the First and Second Graphitic Material

The gas is inserted into the chamber 12 at a rate of up to 1500 standard cubic centimetres per minute.

The graphitic material, for example a known graphene stack 50 as shown in FIG. 8, is placed in the plasma chamber 12 as the starting material. An oxygen plasma process is then applied for a minimum of 10 minutes and a maximum of 60 minutes to clean the graphitic material. The reactor barrel was rotating at more than 30 rpm. During the oxygen cycle UV photons and/or ions bombard the surface creating mono, di and tri vacancies which provide sites for oxygen groups.

An argon exfoliating cycle is then implemented under similar processes and conditions to the cleaning process. The exfoliation process causes the stacks of graphene to twist and buckle, providing graphene flakes whereby some spaces between layers are significantly greater than the space between other layers. The argon exfoliation cycle also has the effect of cleaning off oxygen groups, leaving sites for bonding desired decorate to the surface of the graphitic material during a further processing stage. Powers of up to 2000 W were applied and a reactor pressure in the range of 0.4 to 1.5 Bar and gas flow rates of up to 1500 sccm were employed. The outside and the inside of the stacks are then intercalated and decorated with the desired electro-active material. This intercalation and decoration is provided in a plasma environment that is rich in disassociated molecules of compounds that carry the relevant electro-active material. The decoration and intercalation is applied for a minimum of 10 minutes to a maximum of 60 minutes.

The opening of the graphitic material into graphene stacks and the intercalation of the electro-active material is contemporaneous.

A second Oxygen process is then applied which removes the outer electro-active decorates, whilst leaving the inner decorates intact. This process is applied for between 10 to 60 minutes.

The output from the reactor is a composite material in the form of a powder particle comprising the intercalated electro-active components within the wavy graphitic structure. A plurality of the composite materials 1 are used to form the powder.

Production of a Particle Dispersion

A binder material (not shown), for example PTFE, is then mixed with an organic solvent and the powder is added to the solution (which is a liquid medium) and is milled for 3 hours, to obtain a slurry. The resulting particle dispersion is used as a surface transferable material.

Production of an Electrode

To form an electrode 51 as shown in FIG. 9, the slurry (not shown) is spread on a conductive substrate, using a slot die coating technique, or alternatively the slurry may be applied to a non-conducting substrate previously treated with a conductive material. The coating on the electrode 51 is dried under a vacuum at 125° C. for 5 minutes. This produces a coherent film or layer on the substrate 48. The coating process is repeated until a coating of the desired thickness is achieved. Suitable coating thicknesses range from 0.3 microns to 25 microns.

The formation of a slurry incorporating a plurality of the composite materials enables current printing or coating technology to be utilised which allows rapid and easily reproducible production of the electrodes 51.

Production of an Anode

Method 1

For the anode 49, as shown in FIG. 10, the electro-active material of choice is silicon 10 which is deposited by decoration and intercalation between the friable graphene layers 5 and on the outer surface 11 thereof to form the composite material 1. The first and second material 2, 3 of the composite material 1 were produced as described above. After the argon exfoliation step, hexamethyldisiloxane in an argon carrier gas was introduced into the chamber 12 via a bubbler system. A plasma was generated during a treatment which lasted 10-60 minutes. It was found to be advantageous to rotate the reactor at 1 rpm to evenly expose the nanoparticles to the plasma but to avoid over exposure to UV photons. The resulting material comprises composite materials 1 which are substantially coated with silicon 10.

The silicon coated composite material is subjected to a further treatment step using a microwave treatment. Most specifically the material was subjected to a microwave induced plasma. This resulted in the formation of silicon nano-pods on the surface of the graphitic material as shown in FIGS. 4 and 10.

Method 2

The graphitic starter material is cleaned with argon gas and the cleaned graphitic material is subsequently functionalised with Oxygen gas. Polydimethylsiloxane hexamethyldisiloxane vapour is then supplied to the plasma chamber. The resulting material comprises composite materials 1 which are substantially intercalated and coated with silicon 10.

In both method 1 and method 2, the silicon is in the form of sub-micron sized pods of silicon, which are a plurality of discrete structures or “islands” which lodge themselves on to the upper and lower surfaces of the wavy stacks. The nano-pods form very thin and interrupted layers on the surfaces which are more durable than thicker layers of silicon and which are self-healing, whereby any cracks formed through the expansion and contraction of the silicon may be repaired. It can be seen that the silicon is present as a plurality of discrete “nano-pods” having dimensions less than 500 nm and often less than 100 nm. This gives rise to useful properties, such as an ability for the silicon nano-pods to expand and contract independently of each other, whilst the graphenes 8 provide a stable architecture which negates the detrimental effects of the silicon's expansion and contraction. Therefore the “islands” of silicon are free to expand and contract without affecting the structural integrity of the graphene. This provides the potential for a material 1 applicable to form a stable anode that can cope with multiple charge/discharge cycles with minimal structural damage. Therefore, a greater number of lithium ions can be accommodated in the electrode whilst the flexibility of the graphene sheets and the space between the pods can accommodate the volume changes of the silicon, thereby alleviating the volume effect during cycling.

The graphenes 8 high conductivity facilitates the flow of electrons, whilst the silicon high capacity nano-pods provide the lithium ion storage.

Free ions are permitted to travel through defects or holes in the wavy graphene sheets 8 preventing logjams of ions at the anode thereby substantially reducing the time it takes the battery to recharge. Free unhindered movement of ions also reduces the risk of elevated temperatures being created during the charging process. Ultimately, in light of the above-mentioned benefits this composite material 1 provides an improved anode 49 efficiency.

Production of a Cathode

For the Cathode 52, as shown in FIG. 11, the electro-active material (or active cathode component) of choice is sulfur 53. The sulfur 53 is introduced into the plasma chamber 12 in a powdered form. The ratio to sulfur 53 and graphitic stacks 2,3 introduced into the chamber 12 is 20 wt % to 80 wt %. A sublimation process is then performed to apply the sulfur 53 to the graphitic stack having a major spacing 4. The free sulfur particles are substantially captured within the electrodes carbon architectural edifices or gaps providing a means of both preserving the sulfur and providing the electrical contact required during cycling. Sulfur 53 is co-valently bonded to the surface of the layers 5, 5a. Further, free sulfur is embedded within the gaps 4 of the wavy stacked structure and is robustly sustained therein due to its attraction to the particles of sulfur bonded to the carbonaceous architecture. The sulfur/graphene composite architecture adsorbs any polysulfide intermediates. This cathode arrangement 52 (at the very least) significantly reduces the dissolution loss of sulfur, safeguarding both a high coulombic efficiency of the cathode as well as providing a long life cycle of the cathode. This ultimately provides a stable carbon sulfur electrode with an improved cathode 52 efficiency.

Fabrication of a Lithium Ion Battery

The lithium ion battery 54, as shown in FIG. 12, is formed of multiple lithium ion cells (only one shown) that are encased in a prismatic metal housing (not shown). The lithium ion cell is a three sheet component. A multiplicity of the three sheet components are pressed together and located within the metal housing whereby the three sheet component is made up of a positive electrode (anode) 49, a negative electrode (cathode) 52 and a separator 55. The three sheet components are submerged within an electrolyte 56 within the metal casing (not shown).

The electrolyte 56 is a structured gel, for example an aqueous gel, containing an ionisable species, for example lithium. FIG. 12 shows the electrolyte to be lithium sulphide. The separator 54 is a very thin sheet of micro perforated polymer that separates the anode 49 form the cathode 52. Whilst allowing the ions 57 to pass there-through. The polymer 55 as shown in FIG. 12 is polyethylene.

The negative electrode is the sulfur intercalated cathode 52 described above and the positive electrode is the silicon intercalated anode 49 described above, therefore both the cathode 52 and the anode 49 are provided with electro-active material 6, 7.

On charging the battery, ions 57 move through the electrolyte 56 from the positive electrode 49 to the negative electrode 52 and attach themselves to the graphitic material 2,3. During discharge, the lithium ions 57 move back to the electro-active anode 49 from the cathode 52 and power a load 58.

Use of the silicon decorated/intercalated anode 49 and sulfur decorated/intercalated cathode 52 of the invention allows for the battery 54 to be manufactured using well established printing processes which are easy to reproduce and relatively inexpensive to implement.

Various modifications to the principles described above would suggest themselves to the skilled person. For example, instead of graphene stacks 50, the graphitic starter material may instead be particles of carbon, or fullerenes or bundles of carbon nano tubes or a mixture thereof. However, in each case the space or gap 4 is provided prior to the electro-active particle 6, 7 being introduced. This is significantly different to known techniques implemented in the field, which rely on wrapping structures around the decorate.

For a composite material 1 to be used on a lithium sulfur cathode 52 the graphene stacks may instead be loaded with a high sulfur content doped with Nitrogen. The Nitrogen doping better facilitates the penetration of Lithium ions across the graphene and restrains the sulfur's tendency to leach out due to the strong chemical bonding between the sulfur and the nearby nitrogen atoms.

Alternatively, the wet binder (not shown) may be polyurethane, polyethylene, polypropylene, polyvinylidene difluoride, styrene-butadiene rubber, carboxymethyl cellulose or organic polymers that conduct electricity such as polyaniline or a binder may not be applied at all. In fact it is preferable not to use a binder since they tend to be insulating. The choice of the binder system will ultimately depend on the thermoplastic or cross-linkable polymer species to be implemented.

Instead of an organic material the binder and composite material mix may be added to water.

Instead of a slurry, the powder may be mixed to form a paste or an ink, depending on the desired rheology. The ink is of particular interest since it can be printed onto a desired substrate with ease.

Additional volumes of electro-active materials may be added to the slurry if desired in addition to the electro-active material already applied to the wavy graphene stack 1a.

The coating method, be it using static bed or reel to reel techniques, may be implemented and may include flexographic printing, screen-printing or stencil printing as alternatives to slot die printing.

In the case of use of cross-linkable binders the coating must be cured instead of dried (which is the technique used for thermoplastic binders).

Other metal oxides may be used for material to be applied to the anodes and cathode as would be obvious.

As an alternative to bead milling, the coating may be formed by roll milling or high speed dispersing techniques.

Instead of using a wet method of forming the electrode (using a slurry or ink), a dry method may be implemented, whereby a treatment may be performed on the stacks to decorate the surface of the composite particles with a binding material. A suitable binding material is Polyethylene, Polypropylene or a rubber (such as Nitrile Butadiene or Styrene Butadiene rubber). The resulting material is then compression moulded or casted to form the electrode. This dry method provides a solvent free process forming an electrode having a higher electrode specific surface area, higher energy storage capacity and an improved or higher packing density compared to the wet method.

The polymer 54 of the battery 53 may be thermoset polymer or a thermoplastic. The polymer may be synthetic or a natural polymer such as a biopolymer. The polymer may be an epoxy-based polymer, a polyolefin such as polyethylene or polypropylene, polyurethane, polyester, polyamide, an acrylic polymer or a methacrylic polymer. The polymer may be a homopolymer or a co-polymer of suitable type.

Instead of a non-aqueous gel, the electrolyte 55 may be a non-aqueous gel, or may instead be a dispersion, emulsion or solid. Further the ionisable species may be potassium, ammonium or salts.

Instead of a prismatic metal casing (not shown), a cylindrical casing may be used for the battery, wherein the three components located within the casing form a continuous, spiral structure.

In an alternative embodiment of the invention only the anode 49 is provided with electro-active material and no electro-active material is applied to the cathode 52.

Alternatively, the second oxygen process is not provided and the external surface 11 of the composite material retains the decorate 6. In this scenario an outer protective layer or protective material (not shown) may be applied to the outer surface of the composite material 1, so as to protect the outer surface from electrolyte poisoning. For example a protective layer may be formed by providing a graphene stack arrangement without the intercalation process. In this process the surface of the stack is doped with a species that may promote conductivity such as nitrogen or amines. The output from the plasma chamber is a clean graphene stack in the form of a powder that can be combined with a binder and mixed with a solvent to form a solution.

Therefore, the cathode and/or the anode also include decorates on the external surface of the graphitic material. In the case that the anode has the electro-active material on its outer surface, a silicon encapsulating layer is provided by applying a graphitic carbon protective outer layer or layers 1a. Similarly in the case of the cathode 52 having electro active material 6 on its outer surface, a sulfur encapsulating layer is provided by applying a graphitic carbon protective outer layer or layers 1a. An indefinite number of electro-active layers and protective coating layers (if required) may be applied to increase the protection of the electro active materials 6 from the detrimental effects of electrolyte 55 electro-active material saturation and reactions.

Alternatively the composite material is a nano-composite material, whereby at least one dimension of the material is less than 1000 nm.

Whilst it has been described above that 20% sulfur to 80% graphene stacks is suitable to enable sulfur sublimation in the reactor, other ratios may be implemented as desired, for example 50/50.

Therefore, use of the composite material in electrodes for Lithium, ion batteries provides batteries that are longer lasting, have improved energy storage, charge quicker than previously known batteries and are cost effective to produce, whilst ultimately being commercially feasible (and mass producible).

As an alternative to sulfur, the active cathode components may instead be selected from the group comprising: Cobalt-based lithium-ion LiCOO₂ (LCO), Nickel Cobalt Aluminium (NCA), Spinel-based lithium-ion LiMn₂O₄(LMO), Nickel Cobalt Manganese (NCM) or Lithium Iron Phosphate (LFP).

Instead of a rechargeable battery, e.g. a lithium ion battery, an alternative energy storage device may comprise the composite material of the invention.

1-69. (canceled)

70. A composite material for use as an electrode component including:
a first and second substantially separate and distinct graphitic material, the first graphitic material being spaced apart from the second graphitic material; and
a decorate arranged within the space between the first and second graphitic material by means of intercalation.

71. A composite material according to claim 70 having dimensions on the nano-scale so as to form a nano-composite material.

72. A composite material according to claim 70, wherein the first and second material are the same material.

73. A composite material according to claim 70, wherein the first and second material are platelet-like.

74. A composite material according to claim 70, wherein the first and/or second material have an undulating structure.

75. A composite material according to claim 70, wherein the first and second graphitic material are in a stacked arrangement so as to form a first and second layer of the stack and the decorate is positioned between the first and second layer of the stack.

76. A composite material according to claim 75, wherein the first layer is a first sub-structure and the second layer is a second sub-structure, the first and second sub-structures including a stack of graphitic material layers, in which separation between successive stacked substructures is greater than the separation between successive graphitic material layers in each sub-structure.

77. A composite material according to claim 76, wherein the separation between successive stacked substructures is variable.

78. A composite material according to claim 77, wherein the separation between successive stacked substructures increases the surface area of the graphitic material capable of receiving the decorate.

79. A composite material according to claim 76, in which the separation between successive stacked sub-structures is in a range 2 to 100 nm, preferably 5 to 50 nm, more preferably 10 to 30 nm, most preferably 10 to 20 nm and/or in which the sub-structures each have a thickness which is in the range of 1 to 15 nm, preferably 1 to 4 nm.

80. A composite material according to claim 76, in which each sub-structure includes a stack of between 2 and 12 graphitic material layers, preferably 3 graphitic material layers.

81. A composite material according to claim 76 in which the sub-structures are nano-platelet-like sub structures.

82. A composite material according to claim 76, in which the sub-structures each have a stack thickness, and the stack thicknesses are less than the separation between successive stacked sub-structures.

83. A composite material according to claim 70, in which the first and second material have a net negative charge.

84. A composite material according to claim 70, wherein the graphitic material is graphene and/or wherein the decorate is an electro-active material.

85. A composite material according to claim 70, wherein the first and/or second layer contains defects or holes arranged therein for permitting the transfer of ions there-through.

86. A composite material according to claim 70, in the form of a powder particle.

87. A composite material according to claim 70, wherein the external surface of the composite material is substantially devoid of any decorate.

88. A composite material according to claim 70, wherein the surface of the stacks are decorated with a binding material and/or wherein the binding material is one of Polyethylene, Polypropylene or a rubber capable of being moulded or casted into a desired shape.

89. A particle dispersion comprising at least one composite material according to claim 70 combined with a liquid medium.

90. A particle dispersion according to claim 89, wherein the liquid medium is a Solvent.

91. A particle dispersion, according to claim 89, wherein the composite material and the liquid medium form a slurry.

92. A particle dispersion, according to claim 89, wherein the composite material structure and the liquid medium form an ink.

93. An electrode, for use in an energy storage device comprising the composite material of claim 70.

94. An electrode, for use in an energy storage device, comprising the particle dispersion of claim 89.

95. An electrode, for use in an energy storage device according to claim 94, wherein the particle dispersion is applied to the surface of a conductive membrane.

96. An electrode according to claim 93, wherein the decorate material is an active cathode component selected from the group comprising Cobalt-based lithium-ion, Nickel Cobalt Aluminium, Spinel-based lithium-ion, Nickel Cobalt Manganese, Lithium Iron Phosphate and sulfur thereby forming a negative electrode.

97. An electrode according to claim 93, wherein the active cathode component is covalently bonded to a surface of he first and second material and/or including nitrogen.

98. An electrode according to claim 93, wherein the decorate is silicon.

99. An electrode according to claim 98, wherein the silicon applied has a substantially spherical structure and/or, wherein the silicon has a nano-pod structure and/or wherein the spacing between the first and second material is at least 0.5 nm permitting expansion and contraction of the silicon when a charge/discharge cycle is applied.

100. A method of fabricating a composite material including creating at least one space between a first and second graphitic material and subsequently inserting electro-active material within the at least one space by means of intercalation.

101. A method according to claim 100, wherein the creation of the at least one space between a first and second graphitic material and the intercalation of the electro-active material within the at least one space are contemporaneous and/or including subjecting a starting material to a plasma treatment and/or in which the plasma treatment includes generating plasma using a plurality of electrodes which are moved during the plasma treatment to agitate the starting material and/or the composite material.

102. A method according to claim 101, in which the plasma treatment includes a cleaning step, preferably using a plasma in an oxygen containing gas, most preferably using an oxygen plasma and/or in which the plasma treatment includes an exfoliating plasma step for exfoliating the starting material, preferably using a noble gas plasma, most preferably using an argon plasma.

103. A method according to claim 102 further comprising a composite material including a second cleaning process for substantially removing any electro active material located on the external surface of the composite material.

104. A method according to claim 100, comprising a microwave induced finishing treatment, preferably a microwave induced plasma treatment.

105. A method of fabricating a composite material in a plasma chamber including:
inserting a raw carbonacious material into the chamber;
carbonaceous twisting and buckling the raw carbonacious material by the application of a plasma to form a host region,
inserting electro-active materials within the host region so as to form a composite material.

106. A method of fabricating a composite material according to claim 105, further comprising the step of applying a cleaning process on the raw carbonacious material.

107. A method of fabricating a composite material according to claim 106 in which the electro-active material is inserted by sulfur sublimation.

108. A method of forming an anode comprising:
placing a graphitic material within a plasma chamber;
cleaning the graphitic material with a plasma formed in the presence of argon gas;
functionalising the graphitic material with a plasma formed in the presence of oxygen gas; and
introducing polydimethylsiloxane hexamethyldisiloxane vapour into the plasma chamber so as to insert silicon within the graphitic material.

109. A method of producing a defect in a graphitic material in a plasma chamber comprising:
providing an impact between the graphitic material and a localised ion beam, electrons or radiation at a region proximate to an electrode so as to produce a localised temperature at that region which is greater than the ambient temperature within the plasma chamber so as to produce a defect in the graphitic material.

110. A method according to claim 109, wherein the ambient temperature within the reactor is less than 400K and the localised temperature at the electrode is more than 550K and/or wherein the localised temperature is less than 3000K and/or wherein the localized temperature occurs for a time period of less than 10 nano seconds.

111. An energy storage device, incorporating the composite material of claim 70.

112. An energy storage device, comprising the particle dispersion of claim 90.

113. An energy storage device, incorporating the electrode of claim 93 as a cathode.

114. An energy storage device, incorporating the electrode of claim 99 as an anode.

115. An energy storage device according to claim 111, wherein the energy storage device is a rechargeable battery

116. An energy storage device according to claim 115, wherein the rechargeable battery is a lithium ion battery.

117. An energy storage device having an anode and a cathode comprising the composite material of claim 70, wherein the cathode further comprises sulphur and the anode further comprises silicon.

118. An energy storage device according to claim 117, wherein the energy storage device is a rechargeable battery.

119. An energy storage device according to claim 117, wherein the energy storage device comprises a Lithium ion battery.
